(19) United States
(12) Patent Application Publication
(10) Pub. No.: US 2024/0304041 A1
(43) Pub. Date: Sep. 12, 2024

(54) FAULT DIAGNOSIS APPARATUS AND METHOD OF ECU FOR VEHICLE

(71) Applicant: HL MANDO CORPORATION, Pyeongtaek-si (KR)

(72) Inventor: Taehyoung KIM, Yongin-si (KR)

(21) Appl. No.: 18/220,763

(22) Filed: Jul. 11, 2023

(30) Foreign Application Priority Data
Mar. 7, 2023 (KR) 10-2023-0029805

(51) Int. Cl. G07C 5/08; G01R 19/165; G01R 31/00

(52) U.S. Cl. CPC G07C 5/0825; G01R 19/1659; G01R 31/007; G07C 5/0808

(57) ABSTRACT

Disclosed herein are a fault diagnosis apparatus and method of a vehicle ECU. The fault diagnosis apparatus of a vehicle ECU, which has a functional safety system configured to detect a fault remaining beyond a preset diagnostic test interval from its occurrence time as a confirmed fault, includes a sensor configured to output one or more of signals corresponding to an input/output current and voltage of the vehicle ECU. The fault diagnosis apparatus further includes a diagnoser configured to detect the fault occurrence and termination of the vehicle ECU during the diagnostic test interval based on a signal received from the sensor and detect a potential fault of the vehicle ECU based on the number of the detected fault occurrence and termination of the vehicle ECU.

### CROSS-REFERENCE TO RELATED APPLICATION

This application claims the benefit of Korean Patent Application No. 10-2023-0029805, filed on Mar. 7, 2023 in the Korean Intellectual Property Office, the disclosure of which is incorporated herein by reference.

### BACKGROUND

### 1. Field

Embodiments of the present disclosure relate to a fault diagnosis apparatus and method of an electronic control unit (ECU) for a vehicle and, more particularly, to a fault diagnosis apparatus and method of an ECU for a vehicle, which are capable of detecting an indication of a fault of the ECU for a vehicle in advance.

### 2. Description of the Related Art

In recent times, vehicles are being equipped with more and more electronic functions, and accordingly, various electronic devices and various types of electronic control units (ECUs) for controlling the devices are being installed and utilized in vehicles.

Generally, when a fault occurs due to a defect of ECU hardware and is finally confirmed after a predetermined time for detecting the fault has elapsed, such electronic devices for vehicles inform a driver or manager of the fault by turning on a warning light.

However, when power is continuously applied to a vehicle during such a process, there is a problem in that a partial damage of an ECU may be expanded to the entire vehicle and may cause, in a worst case, a fire that results in a damage of a vehicle itself.

Especially, due to the characteristics of faults, an ECU experiences a fault intermittently since it is an individual component or due to an assembly-related problem, and the fault disappears and reappears repeatedly according to conditions such as temperature and the like.

Accordingly, for vehicles with various electronic devices, a measure is prepared for accurately detecting an indication of a fault in advance and informing a driver or manager before the fault of a vehicle ECU for controlling the various electronic devices is confirmed.

### SUMMARY

Therefore, it is an aspect of the present disclosure to provide a fault diagnosis apparatus and method of a vehicle ECU, which are capable of preventing a potential fault from being developing into a serious fault in advance by detecting the potential fault before a final fault of the vehicle ECU is confirmed and notifying a driver or manager of the potential fault.

Another aspect of the present disclosure is to provide a fault diagnosis apparatus and method of a vehicle ECU, which are capable of detecting a potential fault of the vehicle ECU more accurately and continuously.

Additional aspects of the disclosure will be set forth in part in the description which follows.

In accordance with one aspect of the present disclosure, a fault diagnosis apparatus of a vehicle ECU with a functional safety system configured to detect a fault remaining beyond a preset diagnostic test interval from an occurrence time as a confirmed fault includes a sensor configured to output one or more of signals corresponding to an input/output current and voltage of the vehicle ECU and a diagnoser configured to detect fault occurrence and termination of the vehicle ECU during the diagnostic test interval based on the one or more signals received from the sensor and detect a potential fault of the vehicle ECU based on the number of the detected fault occurrence and termination of the vehicle ECU.

In some embodiments, the diagnoser is configured to detect the fault occurrence and termination of the vehicle ECU based on deviation and return of the signal received from the sensor from and to a preset allowable range of input/output current and voltage.

In some embodiments, the diagnoser is configured to detect the confirmed fault of the vehicle when the signal received from the sensor deviates from the preset allowable range of input/output current and voltage and remains beyond the diagnostic test interval.

In some embodiments, the diagnostic test interval is set to 100 ignition cycles (IG) of a vehicle.

Herein, in some embodiments, the diagnoser is configured to detect the potential fault of the vehicle ECU when the number of fault occurrence and termination of the vehicle ECU is greater than or equal to 10 during the diagnostic test interval.

In addition, in some embodiments, the diagnoser is configured to initialize the diagnostic test interval when the number of fault occurrence and termination of the vehicle ECU is less than 10 during the diagnostic test interval.

In some embodiments, the sensor includes a current sensor provided on each of phases of the vehicle ECU and an input/output voltage sensor of the vehicle ECU.

In some embodiments, the vehicle ECU includes the sensor and the diagnoser.

In some embodiments, the diagnoser is configured to turn on a warning light provided in a vehicle when the confirmed fault or the potential fault of the vehicle ECU is detected.

Herein, in some embodiments, the diagnoser is configured to turn on the warning light so that the confirmed fault and the potential fault of the vehicle ECU are distinguishable from each other.

In accordance with another aspect of the present disclosure, a fault diagnosis method of a vehicle ECU with a functional safety system configured to detect a fault remaining beyond a preset diagnostic test interval from an occurrence time as a confirmed fault includes detecting fault occurrence and termination of the vehicle ECU during the diagnostic test interval based on one or more signals corresponding to an input/output current and voltage of the vehicle ECU and detecting a potential fault of the vehicle ECU based on the number of the detected fault occurrence and termination of the vehicle ECU.

In some embodiments, the detecting of the fault occurrence and termination of the vehicle ECU is performed based on the deviation and return of one or more of signals corresponding to the input/output current and voltage of the vehicle ECU from and to a preset allowable range of input/output current and voltage.

In some embodiments, the detecting of the confirmed fault of the vehicle ECU is performed based on the deviation and maintenance of one or more of signals corresponding to the input/output current and voltage of the vehicle ECU deviating from the preset allowable range of input/output current and voltage and remaining beyond the diagnostic test interval.

In some embodiments, the diagnostic test interval is set to 100 ignition cycles of a vehicle.

Herein, in some embodiments, the detecting of a potential fault of the vehicle ECU is performed based on the number of fault occurrence and termination of the vehicle ECU being greater than or equal to 10 during the diagnostic test interval.

In addition, in some embodiments, initializing the diagnostic test interval is performed based on the number of fault occurrence and termination of the vehicle ECU being less than 10 during the diagnostic test interval.

In addition, in some embodiments, the initializing of the diagnostic test interval includes initializing the number of fault occurrence and termination of the vehicle ECU.

In some embodiments, the detecting of the confirmed fault or the potential fault of the vehicle ECU is performed based on each signal being output from a current sensor provided on each of phases of the vehicle ECU and an input/output voltage sensor of the vehicle ECU.

In some embodiments, the detecting of the confirmed fault or the potential fault of the vehicle ECU includes turning on a warning light provided in a vehicle.

Herein, in some embodiments, the turning on of the warning light includes turning on the warning light to make the confirmed fault and the potential fault of the vehicle ECU distinguishable from each other.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a view illustrating a state in which an operation of a fault diagnosis apparatus of a vehicle ECU is applied to an international standard for automotive functional safety in accordance with some embodiments of the present disclosure;

FIG. 2 is a block diagram illustrating a configuration of the fault diagnosis apparatus of the vehicle ECU in accordance with some embodiments of the present disclosure;

FIG. 3 is a block diagram illustrating a configuration of the fault diagnosis apparatus of the vehicle ECU in accordance with some embodiments of the present disclosure;

FIG. 4 is a flowchart illustrating an operation algorithm for detecting a potential fault of an ECU in the fault diagnosis apparatus of the vehicle ECU in accordance with some embodiments of the present disclosure;

FIG. 5 is a flowchart illustrating a process of detecting a confirmed fault of an ECU in a fault diagnosis method of the vehicle ECU in accordance with some embodiments of the present disclosure; and

FIG. 6 is a flowchart illustrating a process of detecting a potential fault of the ECU in the fault diagnosis method of the vehicle ECU in accordance with some embodiments of the present disclosure.

### DETAILED DESCRIPTION

Like numerals refer to like elements throughout the specification. Not all elements of embodiments of the present disclosure will be described, and description of what are commonly known in the art or what overlap each other in the embodiments will be omitted. The terms as used throughout the specification, such as “part”, “module”, “member”, “block”, etc., may be implemented in software and/or hardware, and a plurality of “parts”, “modules”, “members”, or “blocks” may be implemented in a single element, or a single “part”, “module”, “member”, or “block” may include a plurality of elements.

In the present specification, when a part is “connected” to another part, this includes not only a case where the parts are directly connected, but also a case where the parts are indirectly connected, and the indirect connection includes a connection over a wireless communication network.

Also, when a part is referred to as “comprising” a component, it may mean further inclusion of another component not the exclusion thereof, unless explicitly described to the contrary.

In the present specification, it should be understood that, when a member is referred to as being “on” another member, it can be directly on the other member, or one or more intervening members may also be present.

The terms first, second, etc. are used only for the purpose of distinguishing one component from another, and the components are not limited by the terms.

Singular expressions include plural expressions unless the context clearly indicates otherwise.

An identification code in each step is used for convenience of description but is not intended to illustrate an order of steps, and each of the steps may be implemented in an order different from an illustrated one, unless the context clearly indicates a specific order.

An operating principle and embodiments of the disclosed invention will be described with reference to the accompanying drawings.

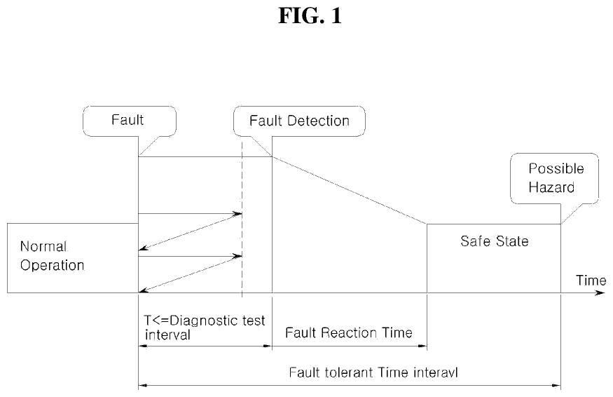

FIG. 1 is a view illustrating a state in which an operation of a fault diagnosis apparatus of a vehicle ECU is applied to an international standard for automotive functional safety in accordance with some embodiments of the present disclosure.

First, referring to FIG. 1, terms may be defined as follows in accordance with the international standard (ISO 26262) for automotive functional safety.

“Normal operation” is defined as a state where no fault occurs. Here, the fault may refer to a measurement error of an input/output sensor and the like.

“Safe state” is defined as a state where a risk for an operating mode of a system is not unreasonable, and this may mean a case where an operating mode intended for the passenger safety, a deteriorated operating mode, or a switch stop mode is activated by detecting, for example, a situation where a fault occurs.

“Fault tolerant time interval (FTTI)” is defined as a time where a single fault or a plurality of faults may exist in a system before a hazardous event occurs, and more specifically, a length of time it takes for a safety mechanism to detect and handle an initial fault and then to finally attain the safe state, and such FTTI should be terminated before a possible hazard occurs.

“Diagnostic test interval” is defined as a time interval of a safety mechanism that is implemented either periodically during the operation of a system or when an event occurs. Accordingly, when an initial fault remains at a diagnostic test interval, it is detected as a confirmed fault, and when the initial fault is recovered before the diagnostic test interval, it is considered as a normal operation.

“Fault reaction time” is defined as a time required to detect a fault and reach a safe state.

Thus, as illustrated in FIG. 1, a fault diagnosis apparatus and method of a vehicle ECU according to some embodiments of the present disclosure are directed to preventing an accident caused by ECU damage attributable to a confirmed fault by detecting a potential fault based on the number of fault occurrence and termination within a diagnostic test interval before an initial fault exceeds the diagnostic test interval and is detected as the confirmed fault.

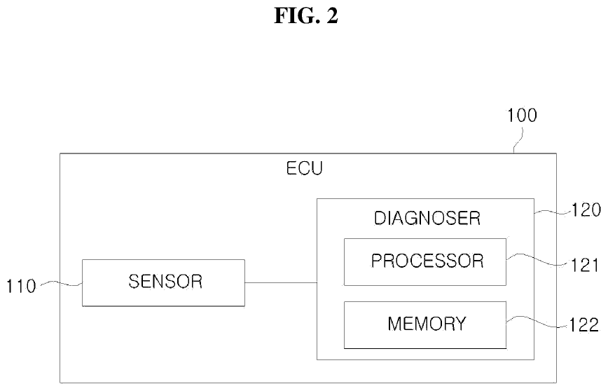

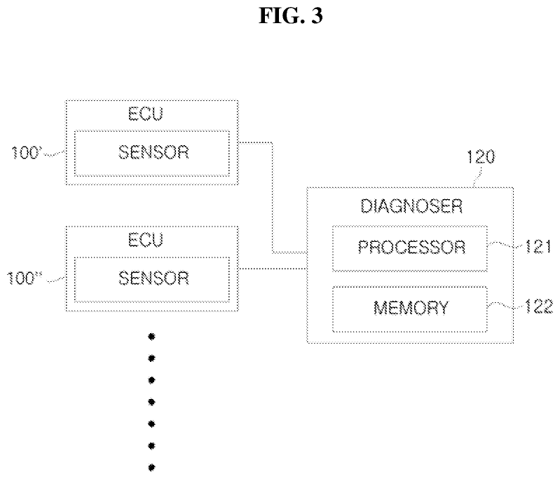

FIGS. 2 and 3 are each a block diagram illustrating a configuration of the fault diagnosis apparatus of the vehicle ECU in accordance with some embodiments of the present disclosure.

Referring to FIGS. 2 and 3, in order to achieve what is stated above, the fault diagnosis apparatus of the vehicle ECU according to some embodiments of the present disclosure includes a sensor 110 and a diagnoser 120.

The sensor 110 is configured to output one or more signals corresponding to an input/output current and voltage of the ECU 100. In some embodiments, the sensor 110 includes a current sensor mounted on each of phases of the ECU 100. In some embodiments, the ECU 100 includes two phases, i.e., A phase and B phase. The current sensor is configured to detect a current applied to or output from each phase and output a signal corresponding to the current and an input/output voltage sensor configured to detect an input/output voltage of the ECU 100 and output a signal corresponding to the input/output voltage. Accordingly, as illustrated in FIGS. 2 and 3, the sensor 110 is integrally provided with the ECU 100.

The diagnoser 120 is configured to detect fault occurrence and termination of the ECU 100, which occurs during the diagnostic test interval, based on one or more signals received from the sensor 110, and detect a potential fault of the ECU 100 based on the number of the detected fault occurrence and termination of the ECU 100.

To this end, the diagnoser 120 is configured to detect the fault occurrence and termination of the vehicle ECU based on the deviation and return of the signal received from the sensor 110 from and to a preset allowable range of input/output current and voltage.

In addition, the diagnoser 120 is configured to detect a confirmed fault of the ECU 100, when the signal received from the sensor 110 deviates from the preset allowable range of input/output current and voltage and remains beyond the diagnostic test interval.

In some embodiments, the diagnoser 120 is configured to turn on a warning light provided in a vehicle or output an alert signal to a portable terminal of a driver or manager, when detecting a potential fault of the ECU 100 or a confirmed fault of the ECU 100. In some embodiments, the diagnoser 120 is configured to output a signal so that the confirmed fault and the potential fault of the ECU 100 can be distinguished from each other.

In some embodiments, the diagnoser 120 is configured to send a report to the portable terminal of the driver or manager that a potential fault or a confirmed fault of the ECU 100 is detected. In some embodiments, the report includes an audio or visual alert on the portable terminal. In some embodiments, the report includes a request to take actions to check the potential fault of the ECU 100 or fix the confirmed fault of the ECU 100. In some embodiments, the report is automatically displayed on the portable terminal without user interaction.

In some embodiments, the diagnoser 120 is configured to send a prompt to the portable terminal of the driver or manager. In some embodiments, the prompt includes an audio or visual alert on the portable terminal. In some embodiments, the prompt provides a guide to the driver or manger to check the potential fault or the confirmed fault. In some embodiments, the prompt is automatically displayed on the portable terminal without user interaction.

As illustrated in FIG. 2 in accordance with some embodiments, the diagnoser 120 is integrally provided with the ECU 100. As illustrated in FIG. 3 in accordance with some embodiments, the diagnoser 120 is provided separately from the ECU 100′ and the ECU 100″ and configured to detect a potential fault of each of a plurality of ECUs 100 and 100′ based on a signal received from a sensor provided in each of the plurality of ECUs.

In some embodiments, the diagnoser 120 includes a processor 121 and a memory 122.

The processor 121 is configured to control an overall operation of the fault diagnosis apparatus of the vehicle ECU in accordance with some embodiments of the present disclosure.

The memory 122 stores a program for the processing or control of the processor 121 and various data for operating the fault diagnosis apparatus of the vehicle ECU in accordance with some embodiments of the present disclosure.

As an example, the memory 122 includes not only a volatile memory such as an S-RAM and a D-RAM but also a non-volatile memory such as a flash memory, a read only memory (ROM), and an erasable programmable read only memory (EPROM).

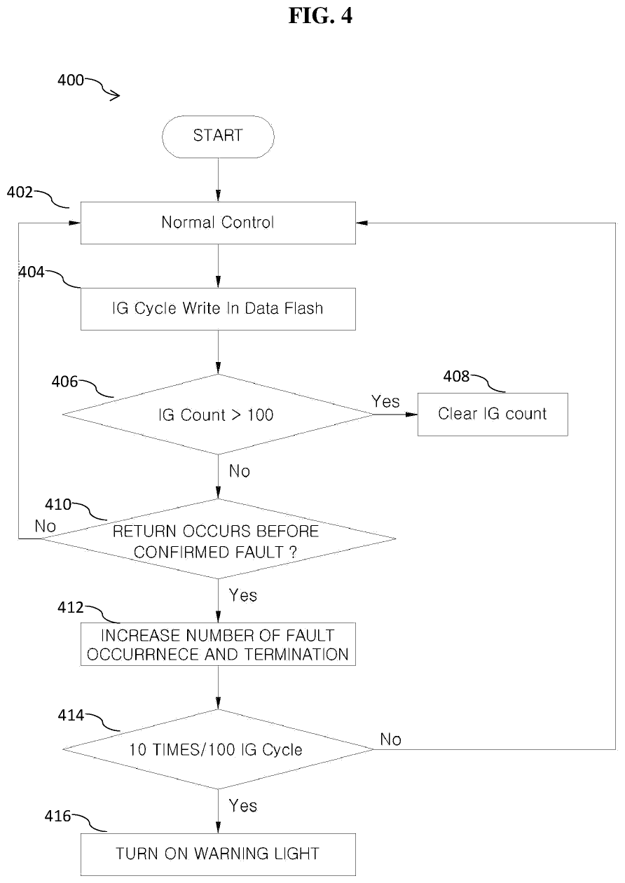

Meanwhile, FIG. 4 is a flowchart illustrating a method 400, which is an operation algorithm, for detecting a potential fault of the vehicle ECU in the fault diagnosis apparatus of the vehicle ECU in accordance with some embodiments of the present disclosure.

The method 400 includes operation 402 in which a vehicle is under a normal control. In some embodiments, at operation 402, the diagnoser 120 initializes a diagnostic test interval and also initializes a counting of the number of fault occurrence and termination of the ECU 100

The method 400 proceeds from operation 402 to operation 404 in which data regarding ignition (IG) cycles of the vehicle are written in a memory, e.g., a flash memory.

In some embodiments, the diagnostic test interval is set to 100 IG cycles of the vehicle. The method 400 further includes operation 406 which determines whether the IG cycles of the vehicle is greater than 100. In some embodiments, the diagnostic test interval is set to a different number of IG cycles. More specifically, in some embodiments, 10 IG cycles of a vehicle, in which the ECU 100 is provided, is considered as a one-day driving mode, and the diagnostic test interval is initialized every 10-day driving mode, that is, every 100 IG cycles.

In response to determining a value of the IG cycles of the vehicle being greater than the set IG cycles, i.e., 100, at operation 406, the method 400 proceeds to operation 408 in which the IG count is cleared or deleted, e.g., from the memory.

In response to determining the value of the IG cycles of the vehicle being not greater than the set IG cycles, i.e., 100 at operation 406, the method proceeds to operation 410. Operation 410 determines whether one or more signals, which correspond to an input/output current and voltage of the vehicle ECU and deviate from a preset allowable range of input/output current and voltage, return to the preset allowable range of input/output current and voltage before a confirmed fault being detected.

In response to determining that the one or more signals, which correspond to the input/output current and voltage of the vehicle ECU and deviate from the preset allowable range of input/output current and voltage, fail to return to the preset allowable range of input/output current and voltage before the confirmed fault being detected at operation 410, the method proceeds to operation 402.

In response to determining that the one or more signals, which correspond to the input/output current and voltage of the vehicle ECU and deviate from the preset allowable range of input/output current and voltage, return to the preset allowable range of input/output current and voltage before the confirmed fault being detected at operation 410, the method proceeds to operation 412 which increases the number of fault occurrence and termination of the ECU 100 during the diagnostic test interval. In some embodiments, the number of such fault occurrence and termination is continuously counted during the diagnostic test interval.

Further, the method proceeds from operation 412 to operation 414 which determines whether a potential fault of the ECU 100 is detected. Operation 414 determines whether the number of fault occurrence and termination of the ECU 100 during the diagnostic test interval is greater than or equal to a permissible number, that is, 10.

In some embodiments, in response to the number of fault occurrence and termination of the ECU 100 during the diagnostic test interval being greater than or equal to the permissible number, that is, 10, the method 400 proceeds to operation 416 in which the diagnoser 120 detects a potential fault of the ECU 100. In some embodiments, at operation 416, the diagnose 120 turns on a warning light provided in the vehicle or outputs an alert signal to a portable terminal of a driver or manager to indicate that the potential fault of the ECU 100 is detected.

In some embodiments, in response to the number of fault occurrence and termination of the ECU 100 during the diagnostic test interval being less than the permissible number, that is, 10, the method proceeds to operation 402.

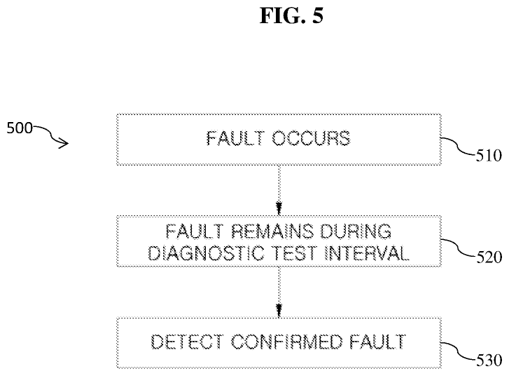

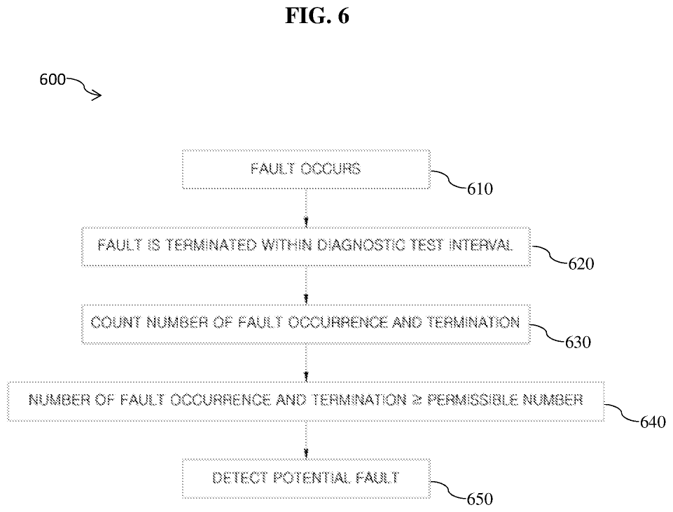

FIG. 5 is a flowchart illustrating a method 500 of detecting a confirmed fault of the vehicle ECU in a fault diagnosis method of the vehicle ECU in accordance with some embodiments of the present disclosure, and FIG. 6 is a flowchart illustrating a method 600 of detecting a potential fault of the vehicle ECU in the fault diagnosis method of the vehicle ECU in accordance with some embodiments of the present disclosure.

Referring to FIG. 5, in the fault diagnosis method of the vehicle ECU according to some embodiments of the present disclosure, as for detecting a confirmed fault of the ECU 100, when determining that a fault occurs (operation 510) and the fault remains beyond a preset diagnostic test interval (operation 520), the fault is determined as a confirmed fault (operation 530).

Herein, operation 510 determines that a fault occurs based on one or more signals corresponding to an input/output current and voltage of the ECU 100. In some embodiments, operation 510 determines that the fault occurs in response to determining each signal, which is output from a current sensor provided in each of A and B phases of the ECU 100 and from an input/output voltage sensor of the ECU 100, deviates from a preset allowable range of input/output current and voltage.

Meanwhile, referring to FIG. 6, in the fault diagnosis method of the vehicle ECU according to some embodiments of the present disclosure, as for detecting a potential fault of the ECU 100, when determining that a fault occurs (operation 610) and the fault is terminated within a preset diagnostic test interval (operation 620), this is counted as one fault occurrence and termination, and the number of such fault occurrence and termination is continuously counted during the diagnostic test interval (operation 630). In some embodiments, the fault occurrence and termination are the deviation and return of one or more of signals corresponding to an input/output current and voltage of the vehicle ECU from and to a preset allowable range of input/output current and voltage.

More specifically, as described above, in some embodiments, 10 IG cycles of a vehicle, in which the ECU 100 is provided, is considered as a one-day driving mode, and the diagnostic test interval is initialized every 10-day driving mode, that is, every 100 IG cycles.

Herein, when the number of the fault occurrence and termination of the ECU 100, which is counted until 100 IG cycles, is greater than or equal to a permissible number of 10 (operation 640), this is detected as the potential fault of the ECU 100 (operation 650).

In addition, as described above, the detecting of the confirmed fault (operation 530) and the detecting of the potential fault (operation 650) each includes turning on a warning light provided in a vehicle in accordance with some embodiments. Further, in some embodiments, the warning light is turned on in a manner so that the detecting of the confirmed fault (operation 530) and the detecting of the potential fault (operation 650) can be distinguished from each other.

Thus, a fault diagnosis apparatus and method of a vehicle ECU according to some embodiments of the present disclosure detect a potential fault of the vehicle ECU in advance before a confirmed fault occurs and notify a driver or manager of the potential fault, thereby preventing the potential fault from developing into a more serious fault such as a damage on the ECU that can result in a fire on the vehicle.

A fault diagnosis apparatus and method of a vehicle ECU according to an embodiment of the present disclosure detect a potential fault of the vehicle ECU more accurately and continuously, thereby improving the reliability of fault diagnosis for the vehicle ECU.

A fault diagnosis apparatus and method of a vehicle ECU according to some embodiments of the present disclosure detect a potential fault of the vehicle ECU in advance before a confirmed fault occurs and notify a driver or manager of the potential fault, thereby preventing the potential fault from developing into a more serious fault such as a damage on the ECU that can result in a fire on the vehicle.

A fault diagnosis apparatus and method of a vehicle ECU according to an embodiment of the present disclosure detect a potential fault of the vehicle ECU more accurately and continuously, thereby improving the reliability of fault diagnosis for the vehicle ECU.

As described above, the disclosed embodiments have been described with reference to the accompanying drawings. Those skilled in the art will understand that the present disclosure can be implemented in a form different from the disclosed embodiments without changing the technical spirit or essential features of the present disclosure. The disclosed embodiments are exemplary and should not be construed as limiting.

What is claimed is:

1. A fault diagnosis apparatus of a vehicle electronic control unit (ECU) with a functional safety system configured to detect a fault remaining beyond a preset diagnostic test interval from an occurrence time as a confirmed fault, the fault diagnosis apparatus comprising:
a sensor configured to output one or more signals corresponding to an input/output current and voltage of the vehicle ECU; and
a diagnoser configured to
detect fault occurrence and termination of the vehicle ECU during the diagnostic test interval based on the one or more signals received from the sensor, and
detect a potential fault of the vehicle ECU based on the number of the detected fault occurrence and termination of the vehicle ECU.

2. The fault diagnosis apparatus of claim 1, wherein the diagnoser is configured to detect the fault occurrence and termination of the vehicle ECU in response to determining the one or more signals received from the sensor deviating from and returning to a preset allowable range of the input/output current and voltage.

3. The fault diagnosis apparatus of claim 1, wherein the diagnoser is configured to detect the confirmed fault of the vehicle ECU in response to the one or more signals received from the sensor deviating from a preset allowable range of the input/output current and voltage and remaining beyond the diagnostic test interval.

4. The fault diagnosis apparatus of claim 1, wherein the diagnostic test interval is set to 100 ignition (IG) cycles of a vehicle.

5. The fault diagnosis apparatus of claim 4, wherein the diagnoser is configured to detect the potential fault of the vehicle ECU in response to the number of the fault occurrence and termination of the vehicle ECU being greater than or equal to 10 during the diagnostic test interval.

6. The fault diagnosis apparatus of claim 4, wherein the diagnoser is configured to initialize the diagnostic test interval in response to the number of the fault occurrence and termination of the vehicle ECU being less than 10 during the diagnostic test interval.

7. The fault diagnosis apparatus of claim 1, wherein the sensor includes:
a current sensor provided in each of phases of the vehicle ECU; and
an input/output voltage sensor of the vehicle ECU.

8. The fault diagnosis apparatus of claim 1, wherein the vehicle ECU includes the sensor and the diagnoser.

9. The fault diagnosis apparatus of claim 1, wherein the diagnoser is configured to turn on a warning light provided in a vehicle in response to the confirmed fault or the potential fault of the vehicle ECU being detected.

10. The fault diagnosis apparatus of claim 9, wherein the diagnoser is configured to turn on the warning light so that the confirmed fault and the potential fault of the vehicle ECU are distinguishable from each other.

11. A fault diagnosis method of a vehicle ECU with a functional safety system configured to detect a fault remaining beyond a preset diagnostic test interval from an occurrence time as a confirmed fault, the fault diagnosis method comprising:
detecting fault occurrence and termination of the vehicle ECU during the diagnostic test interval based on one or more signals corresponding to an input/output current and voltage of the vehicle ECU; and
detecting a potential fault of the vehicle ECU based on the number of the detected fault occurrence and termination of the vehicle ECU.

12. The fault diagnosis method of claim 11, wherein the detecting of the fault occurrence and termination of the vehicle ECU is performed in response to the one or more signals corresponding to the input/output current and voltage of the vehicle ECU deviating from and returning to a preset allowable range of the input/output current and voltage.

13. The fault diagnosis method of claim 11, wherein the detecting of the confirmed fault of the vehicle ECU is performed in response to the one or more signals corresponding to the input/output current and voltage of the vehicle ECU deviating from a preset allowable range of the input/output current and voltage and remaining beyond the diagnostic test interval.

14. The fault diagnosis method of claim 11, wherein the diagnostic test interval is set to 100 ignition (IG) cycles of a vehicle.

15. The fault diagnosis method of claim 14, wherein the detecting of the potential fault of the vehicle ECU is performed in response to the number of the fault occurrence and termination of the vehicle ECU being greater than or equal to 10 during the diagnostic test interval.

16. The fault diagnosis method of claim 14, wherein initializing the diagnostic test interval is performed in response to the number of the fault occurrence and termination of the vehicle ECU being less than 10 during the diagnostic test interval.

17. The fault diagnosis method of claim 16, wherein the initializing of the diagnostic test interval comprises initializing the number of the fault occurrence and termination of the vehicle ECU.

18. The fault diagnosis method of claim 11, wherein the detecting of the confirmed fault or the potential fault of the vehicle ECU is performed based on each signal being output from a current sensor provided on each of phases of the vehicle ECU and an input/output voltage sensor of the vehicle ECU.

19. The fault diagnosis method of claim 11, wherein the detecting of the confirmed fault or the potential fault of the vehicle ECU comprises turning on a warning light provided in a vehicle.

20. The fault diagnosis method of claim 19, wherein the turning on of the warning light comprises turning on the warning light to make the confirmed fault and the potential fault of the vehicle ECU distinguishable from each other.
